(19) United States
(12) Patent Application Publication
(10) Pub. No.: US 2003/0189810 A1
(43) Pub. Date: Oct. 9, 2003

(54) Mother board with four USBs

(76) Inventor: Wan-Tien Chen, Taipei (TW)

Correspondence Address: BACON & THOMAS, PLLC, 625 SLATERS LANE, FOURTH FLOOR, ALEXANDRIA, VA, 22314

(21) Appl. No.: 10/115,906

(22) Filed: Apr. 5, 2002

(51) Int. Cl. H05K 1/00

(52) U.S. Cl. 361/610; 439/61

(57) ABSTRACT

A PC99 mother board includes a substrate, an input port, a LAN port with an INTERNET socket and two USBs provided under the INTERNET socket, a first connecting port mounted on the substrate via a first bracket, a first space defined between the first connector and the third connector, a second space defined between the first connector and the second connector and a second connecting port mounted on the substrate via a second bracket which has a third space defined in the second bracket. Two additional USBs are mounted in either the first or the second bracket so as to provide convenience and compatibility to the user.

### BACKGROUND OF THE INVENTION

1. Field of the Invention

The present invention relates to a mother board, and more particularly to a PC99 mother board with four USBs (Universal Series Bus) so as to enhance the convenience of the mother board in the addition of extra facilities.

2. Description of Related Art

An existing mother board, especially the PC99 mother board, has two sockets respectively mounted on a substrate for connection with the mouse and the keyboard. A LAN socket is mounted on top of two USBs. A first connecting port and a second connecting port are respectively mounted on the substrate. As well known in the art, the provision of the UBS is to provide convenience to the user so that the user enjoys the pleasure of plug & play (P&P). That is, the user may plug in any hard ware to the substrate and immediately use it without going through the rebooting process to wait for the detection and installation of the additional hard ware by the system. Having the USBs on the substrate is quite convenient to the user in that the user is able to facilitate the working speed with any appropriate facility required. With the fast speed of the modern technology, having only two USBs on the substrate seems insufficient to meet the requirements. Therefore, to add two more USBs on the substrate has become a common goal. Recently, a solution to add in two extra USBs on the substrate is to remove the first or the second connecting ports so that after the first or the second connecting ports is removed the space left is ready for the installation of the additional USBs. However, moving the existing first or second connecting ports around on the substrate means that the specification of the mother board is going to encounter a chaos in this field. Because the market is already full of mother boards each with two USBs, changing the existing specification of the mother board will influence a great deal of the market. Also, the cost for fabrication is going to be high, which is counter productive to good marketability.

To overcome the shortcomings, the present invention tends to provide an improved mother board to mitigate and obviate the aforementioned problems.

### SUMMARY OF THE INVENTION

The primary objective of the present invention is to provide an improved mother board with four universal series buses without changing the existing specification.

In order to accomplish the foregoing objective, the mother board has a first connecting port provided with a first output connector, a second output connector and a third connector. The first output connector is mounted on top of the second and the third connectors. The second and the third connectors are arranged in parallel with each other. A bracket is used to hold the first, the second and the third connectors in place. A first space is defined in the first bracket so that the user is able to mount the additional two USBs on the first space such that the objective of adding two additional USBs without changing the existing specification is fulfilled.

Other objects, advantages and novel features of the invention will become more apparent from the following detailed description when taken in conjunction with the accompanying drawings.

### BRIEF DESCRIPTION OF THE DRAWINGS

FIG. 1 is a top plan view of the mother board of the present invention;

FIG. 2 is a side plan view of the mother board in FIG. 1;

FIG. 3 is a side plan view showing the addition of two USBs in the second connecting port;

FIG. 4 is a side plan view showing two USBs are mounted in the first space in the first bracket;

FIG. 5 is a side plan view showing two USBs are mounted in the third space in the second bracket; and

FIG. 6 is a bottom plan view showing the connection between the added two USBs and the substrate.

### DETAILED DESCRIPTION OF THE PREFERRED EMBODIMENT

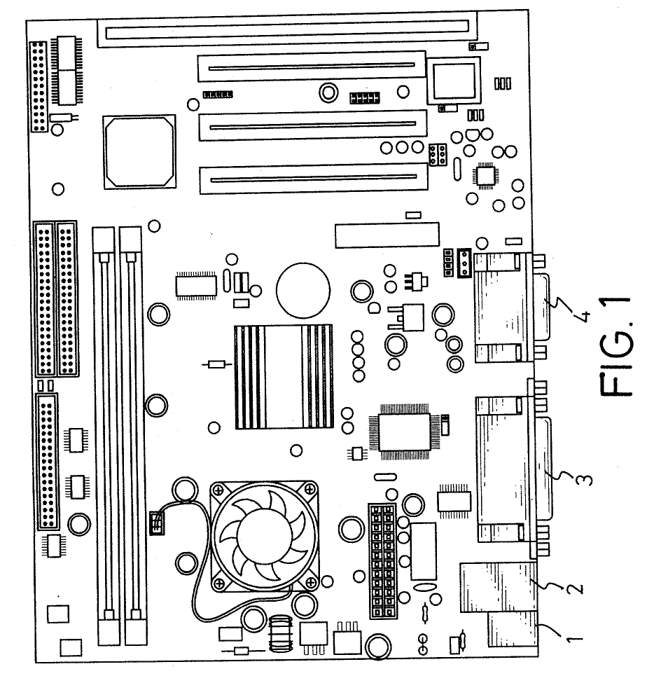

With reference to FIG. 1, a PC99 mother board constructed in accordance with the present invention is shown. The PC99 mother board has an input port (1), a LAN port (2), a first connecting port (3) and a second connecting port (4).

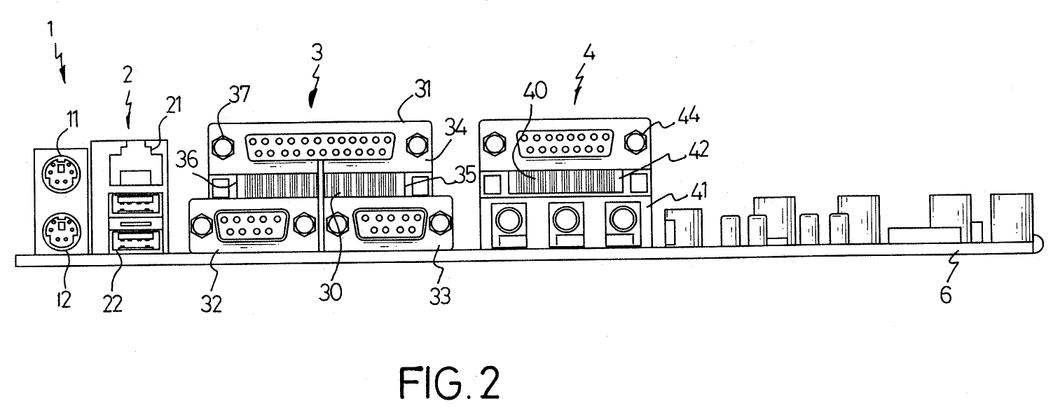

With reference to FIG. 2, the input port (1) of the mother board has a first socket (11) for connecting with a mouse (not shown) and a second socket (12) for connecting with a keyboard (not shown). The LAN port (2) has an INTERNET socket (21) and two USBs (22) provided under the INTERNET socket (21). The first connecting port (3) has a first connector (31), a second connector (32) and a third connector (33). The first, second and the third connectors (31,32,33) are mounted on a substrate (6) via a first bracket (34). That is, the first connector (31) is mounted on top of the second connector (32) and the third connector (33) in parallel with the second connector (32). Due to the provision of the first bracket (34), a first space (35) is defined between the first connector (31) and the third connector (33) and a second space (36) is defined between the first connector (31) and the second connector (32). The second connecting port (4) has a third space (42) defined in a second bracket (41) which is used to securely hold the second connecting port (4) in place relative to the substrate (6). Furthermore, the first connector (31) has connecting pins (30) extending downward to the substrate (6) so as to have connection therewith. The second connecting port (4) has connecting pins (40) extending downward to the substrate (6) so as to have connection therewith.

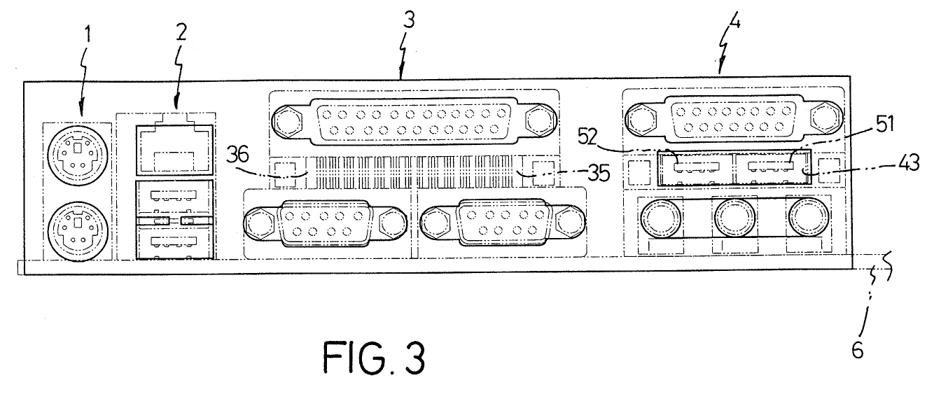

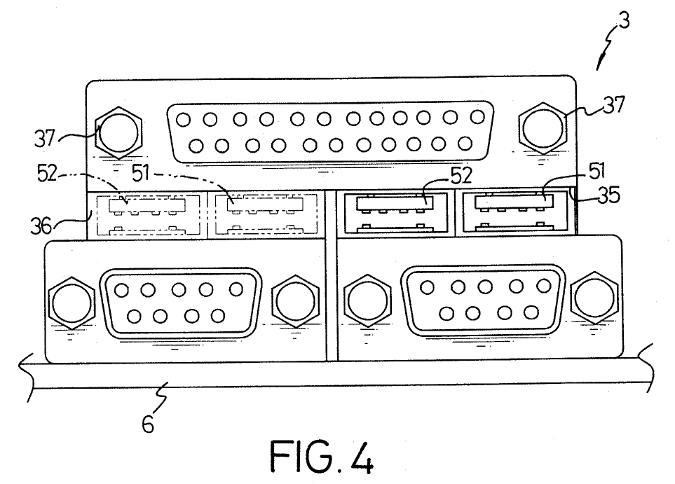

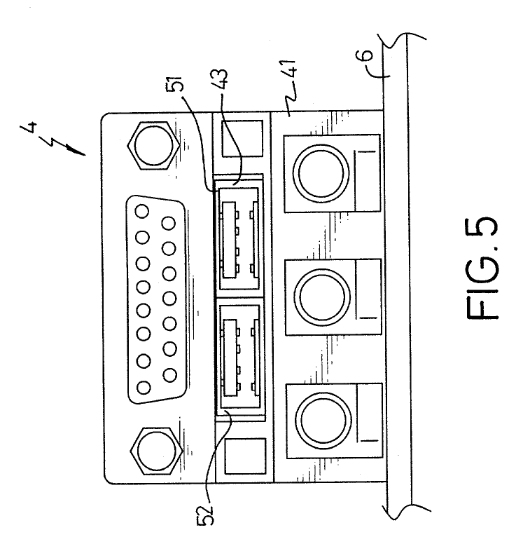

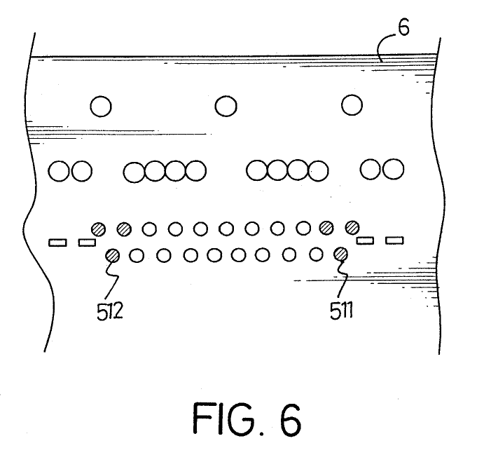

With reference to FIGS. 3, 4, and 5, it is to be noted that when adding two USBs (51,52) to the substrate (6) is necessary, the user may choose to mount the two USBs (51,52) in the third space (43), as shown in FIGS. 3 and 5, the first space (35) or the second space (36), as shown in FIG. 4. After the two USBs (51,52) are added to the substrate (6), a first connecting area (511) and a second connecting area (512) formed on the substrate (6) may be used to have connection with the added USBs (51,52), as shown in FIG. 6. Further, a wire (as shown in dashed lines) from each of the two USBs (51,52) is connected to the screw (37,44) in the first or the second connecting ports (3,4) as ground.

From the foregoing description, it is noted that after the addition of the two additional USBs (51,52), the original specification of the mother board is not changed. Therefore, the cost of alteration is low and the compatibility of the altered mother board is high. Still, the places for mounting the additional USBs are multiple, so that the manufacturer is able to have flexibility to choose where the best place is to meet different requirements.

It is to be understood, however, that even though numerous characteristics and advantages of the present invention have been set forth in the foregoing description together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A PC99 mother board having a substrate, an input port, a LAN port with an INTERNET socket and two USBs provided under the INTERNET socket, a first connecting port mounted on the substrate via a first bracket and having a first connector, a second connector and a third connector, a first space defined between the first connector and the third connector, a second space defined between the first connector and the second connector and a second connecting port mounted on the substrate via a second bracket which has a third space defined in the second bracket, wherein the improvements comprise:
two additional USBs mounted in the first space of the first bracket, wherein the two additional USBs are connected to the substrate and to one of the screws of the first bracket.

2. A PC99 mother board having a substrate, an input port, a LAN port with an INTERNET socket and two USBs provided under the INTERNET socket, a first connecting port mounted on the substrate via a first bracket and having a first connector, a second connector and a third connector, a first space defined between the first connector and the third connector, a second space defined between the first connector and the second connector and a second connecting port mounted on the substrate via a second bracket which has a third space defined in the second bracket, wherein the improvements comprise:
two additional USBs mounted in the second space of the first bracket, wherein the two additional USBs are connected to the substrate and to one of the screws of the first bracket.

3. A PC99 mother board having a substrate, an input port, a LAN port with an INTERNET socket and two USBs provided under the INTERNET socket, a first connecting port mounted on the substrate via a first bracket and having a first connector. a second connector and a third connector, a first space defined between the first connector and the third connector, a second space defined between the first connector and the second connector and a second connecting port mounted on the substrate via a second bracket which has a third space defined in the second bracket, wherein the improvements comprise:
two additional USBs mounted in the third space of the second bracket, wherein the two additional USBs are connected to the substrate and to one of the screws of the second bracket.
